(19) United States
(12) Patent Application Publication
(10) Pub. No.: US 2017/0263565 A1
(43) Pub. Date: Sep. 14, 2017

(54) INTEGRATED CIRCUIT (IC) PACKAGE WITH A GROUNDED ELECTRICALLY CONDUCTIVE SHIELD LAYER AND ASSOCIATED METHODS

(71) Applicant: STMICROELECTRONICS PTE LTD, Singapore (SG)

(72) Inventors: Loic Pierre Louis RENARD, Singapore (SG); Raquel FUNDAN, Johor Bahru (MY)

(21) Appl. No.: 15/068,741

(22) Filed: Mar. 14, 2016

(51) Int. Cl. H01L 23/552; H01L 21/78; H01L 21/48; H01L 23/00

(52) U.S. Cl. CPC H01L 23/552; H01L 24/48; H01L 21/78; H01L 21/4871; H01L 21/4875

(57) ABSTRACT

An integrated circuit (IC) package includes a substrate and an IC die carried by the substrate. An encapsulated body is over the IC die. At least one grounding wire is within the encapsulated body and has a proximal end coupled to the substrate and a distal end exposed on an outer surface of the encapsulated body. An electrically conductive shield layer is on the outer surface of the encapsulated body and in contact with the exposed distal end of the at least one grounding wire.

### FIELD OF THE INVENTION

The present invention refers to the field of integrated circuit (IC) packages, and more particularly, to electrically shielding an IC package.

### BACKGROUND OF THE INVENTION

There exists a general need in wireless communications devices for certain integrated circuit (IC) packages to be isolated from electromagnetic interference (EMI) in order to maintain proper device performance. The electromagnetic interference may be received from, or transmitted to, the environment.

One approach for shielding an IC package from electromagnetic interference is to cover the IC package with a grounded metal enclosure typically called a can. However, this approach may be costly and lacks design flexibility. In addition, the metal can adds weight and adds significant size to the IC package footprint.

Another approach is to use a physical vapor deposition (PVD) process that deposits in a vacuum chamber a conductive layer on an upper surface of the IC package. Sputtering is a type of PVD that involves ejecting material from a target that is a source onto a substrate (such as an IC package) in a vacuum chamber. However, the conductive layer also needs to be grounded which increases the difficulty of the process flow making the IC package. In one approach, clips may be used to ground the conductive layer. Consequently, there is a need for electrically shielding an IC package in a relatively straightforward manner.

### SUMMARY OF THE INVENTION

One aspect is directed to an integrated circuit (IC) package comprising a substrate and an IC die carried by the substrate. An encapsulated body may be over the IC die. At least one grounding wire may be within the encapsulated body and has a proximal end coupled to the substrate and a distal end exposed on an outer surface of the encapsulated body. An electrically conductive shield layer may be on the outer surface of the encapsulated body and in contact with the exposed distal end of the at least one grounding wire.

When the electrically conducted shield layer is formed on the outer surfaces of the encapsulated body, the electrically conducted shield layer is advantageously grounded via the distal end of each grounding wire. This may help to simplify the manufacturing process of the IC package.

In one embodiment of the IC package, a bottom edge of the electrically conductive shield layer may be in contact with the substrate. In another embodiment of the IC package, the bottom edge of the electrically conductive shield layer may be spaced above the substrate.

The IC die may be configured as a flip-chip comprising a plurality of bond pads directly bonded to the substrate. Alternatively, the IC die may be wire bonded to the substrate via a plurality of bond wires.

Each of the plurality of bond wires may have a common cross-sectional size and shape, and the at least one grounding wire may have the common cross-sectional size and shape. Each of the plurality of bond wires may comprise a common metal material, and the at least one grounding wire may comprise the common metal material.

Each of the plurality of bond wires may extend to a common height above the substrate, and the at least one grounding wire may extend to the common height above the substrate, with the common height being within +/−20% of each bond wire and the at least one grounding wire.

The distal end of the at least one grounding wire may be spaced above the substrate. The at least one grounding wire may comprise a plurality thereof having respective distal ends in contact with a same side of the electrically conductive shield layer.

The at least one grounding wire may comprise a plurality thereof having respective distal ends in contact with different sides of the electrically conductive shield layer.

### BRIEF DESCRIPTION OF THE DRAWINGS

FIG. 1 is a cross-sectional side view of an IC package with a wire bonded IC die and a grounded electrically conductive shield layer in accordance with an embodiment of the present invention.

FIG. 2 is a cross-sectional side view of an IC package with a flip-chip IC die and a grounded electrically conductive shield layer in accordance with another embodiment of the present invention.

FIG. 3 is a cross-sectional top view of the IC package illustrated in FIG. 1 without encapsulation and with a single grounding wire contacting each side of the electrically conductive shield layer.

FIG. 4 is a cross-sectional top view of the IC package illustrated in FIG. 1 without encapsulation and with a plurality of grounding wires contacting each side of the electrically conductive shield layer.

FIG. 5 is a cross-sectional view of a plurality of IC dies carried by a substrate with grounding wires in accordance with an embodiment of the present invention.

FIG. 6 is a cross-sectional view of the plurality of IC dies and grounding wires illustrated in FIG. 5 encapsulated.

FIGS. 7a-7c are cross-sectional views of the encapsulated IC dies and grounding wires illustrated in FIG. 6 after being divided.

FIGS. 8a-8c are cross-sectional views of the divided encapsulated IC dies and grounding wires illustrated in FIGS. 7a-7c with a respective electrically conductive shield layer thereon.

FIG. 9 is a cross-sectional view of another embodiment of the IC package illustrated in FIG. 1.

FIG. 10 is a cross-sectional view of the encapsulated IC dies and grounding wires illustrated in FIG. 6 after a portion of the encapsulated body between adjacent IC dies has been removed to expose the respective grounding wires on the outer surfaces thereof.

FIG. 11 is a cross-sectional view of the encapsulated IC dies and grounding wires illustrated in FIG. 10 with an electrically conductive shield layer thereon.

FIGS. 12a-12c are cross-sectional views of the encapsulated IC dies and grounding wires with a respective electrically conductive shield layer thereon after being divided.

FIG. 13 is flowchart for making at least one IC package with a grounded electrically conductive shield layer in accordance with an embodiment of the present invention.

### DETAILED DESCRIPTION OF THE PREFERRED EMBODIMENTS

An embodiment of the present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout, and prime notation is used to indicate similar elements in alternate embodiments.

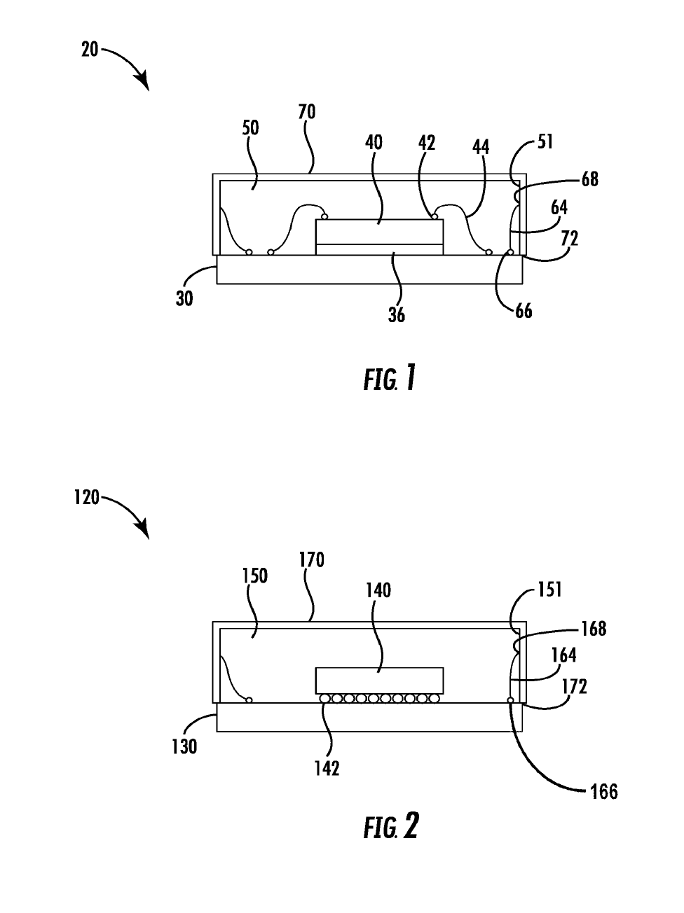

Referring initially to FIG. 1, an integrated circuit (IC) package 20 includes a substrate or leadframe 30 and an IC die 40 carried by the substrate. An adhesive layer 36 secures the IC die 40 to the substrate 30. The IC die 40 includes a plurality of bond pads 42 thereon. A plurality of bond wires 44 extend from the plurality of bond pads 42 to the substrate 30. An encapsulated body 50 is over the IC die 40 and the plurality of bond wires 44. At least one grounding wire 64 is within the encapsulated body 50 and has a proximal end 66 coupled to the substrate 30 and a distal end 68 exposed on an outer surface 51 of the encapsulated body 50. An electrically conductive shield layer 70 is on the outer surface 51 of the encapsulated body 50 and in contact with the exposed distal end 68 of the at least one grounding wire 64.

The IC package 20 illustrated in FIG. 1 is not limited to the IC die 40 being wire bonded to the substrate 30. Alternatively, the IC die may be configured as a flip-chip that is directly bonded to the substrate. As illustrated in FIG. 2, the IC package 120 includes an IC die 140 configured as a flip-chip comprising a plurality of bond pads 142 that are directly bonded to the substrate 130. An encapsulated body 150 is over the IC die 140. At least one grounding wire 164 is within the encapsulated body 150 and has a proximal end 166 coupled to the substrate 130 and a distal end 168 exposed on an outer surface 151 of the encapsulated body 150. An electrically conductive shield layer 170 is on the outer surface 151 of the encapsulated body 150 and in contact with the exposed distal end 168 of the at least one grounding wire 164.

For each of the IC packages 20, 120, the electrically conductive shield layer 70, 170 is on the outer surface 51, 151 of the encapsulated body 50, 151 and in contact with the exposed distal end 68, 168 of the at least one grounding wire 64, 164. The IC die may thus be wire bonded as illustrated in FIG. 1, or may be configured as a flip-chip as illustrated in FIG. 2.

The IC package 20 with the wire bonded IC die 40 will now be discussed in greater detail. The following discussion, less reference to the wire bonds, equally applies to the IC package 120 with the flip-chip IC die 140.

As will be explained in greater detail below, each grounding wire 64 is initially formed to extend between two adjacent IC dies 40 on the same substrate 30 and under the same encapsulated body 50. Each ground wire 64 is connected to ground on the substrate 30 between the two adjacent IC dies 40.

When the encapsulated body 50 is either fully or partially cut between the two adjacent IC dies 40, the at least ground wire 64 extending therebetween is also cut. This forms the distal end 68 of each grounding wire 64 that is exposed on the outer surface of a respective encapsulated body 50. When the electrically conducted shield layer 70 is formed on the outer surfaces 51 of the encapsulated body 50, the electrically conducted shield layer is advantageously grounded via the distal end 68 of each grounding wire 64.

Still referring to FIG. 1, the distal end 68 of each grounding wire 64 is spaced above the substrate 30. Each of the bond wires 44 has a common cross-sectional size and shape, and each grounding wire 64 has the common cross-sectional size and shape. Alternatively, each grounding wire 64 may be a different cross-sectional size and shape than the bond wires 44.

Each of the plurality of bond wires 44 may extend to a common height above the substrate 30, and the at least one grounding wire 64 may extend to the common height above the substrate. The common height may be within +/−20% of each bond wire and the at least one grounding wire. Alternatively, the plurality of bond wires 44 and the at least one grounding wire 64 may extend to different heights above the substrate.

A thickness of the electrically conductive shield layer 70 is within a range of 1-100 microns, for example. The electrically conductive shield layer 70 may include aluminum, copper, chromium, tin, gold, silver, nickel or any combination thereof, titanium, for example. Nonetheless, the electrically conductive shield layer 70 is not limited to these metal materials.

Each of the bond wires 44 comprises a common metal material, and each grounding wire 64 comprises the common metal material. The common metal material may include gold, copper, copper palladium, silver, silver alloys, platinum, or aluminum, for example. The grounding wires 64 are not limited to these metal materials. Alternatively, each grounding wire 64 may be a different metal material than the bond wires 44.

There may be one or more grounding wires 64 in contact with a side of the electrically conductive shield layer 70. For example, each side of the electrically conductive shield layer 70 may have a single grounding wire 64 in contact therewith, as illustrated in FIG. 3.

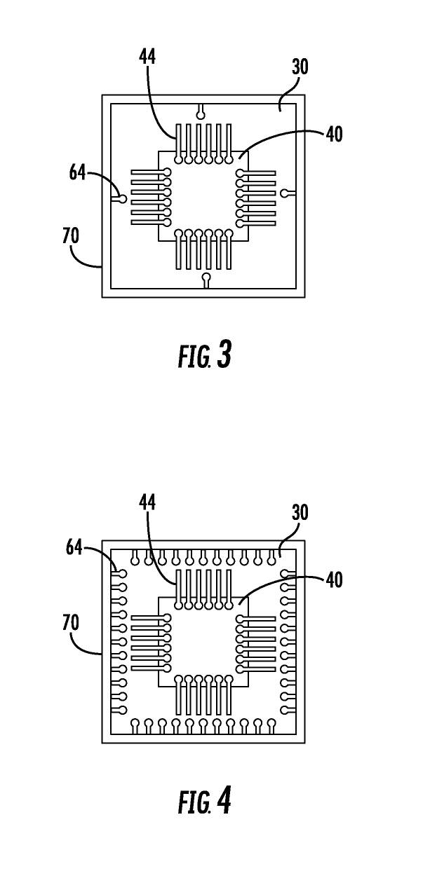

As another example, each side of the electrically conductive shield layer 70 may have a plurality of grounding wires 64 in contact therewith, as illustrated in FIG. 4. In this example, the plurality of grounding wires 64 on each side may be configured as a bonding ribbon or multi-wire planar cable. In a bonding ribbon or multi-wire planar cable, the plurality of grounding wires 64 run parallel to each other on the same flat plane. As a result the cable is wide and flat.

Even though each side of the electrically conductive shield layer 70 in FIGS. 3 and 4 is in contact with at least one grounding wire 64, one to three of the sides may not have a grounding wire. For instance, only one side of the electrically conductive shield layer 70 may be connected to one or more grounding wires 64.

For the IC package 20 illustrated in FIG. 1, a bottom edge 72 of the electrically conductive shield layer 70 is in contact with the substrate 30. This is based on the encapsulated body 50 and the grounding wires 64 being divided or cut between two adjacent IC dies 40 prior to receiving the electrically conductive shield layer 70.

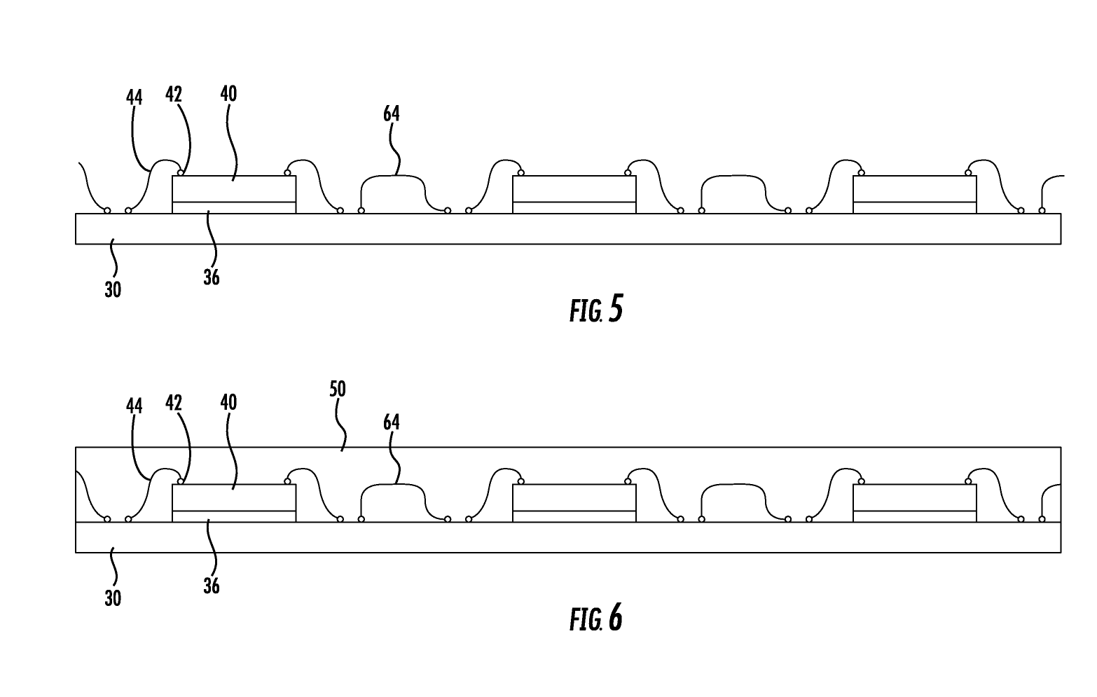

During the manufacturing process, a plurality of IC dies 40 are typically carried by the substrate 30, as illustrated in FIG. 5. The bond wires 44 extend from the bond pads 42 on each IC die 40 to the substrate 30. The grounding wires 64 extend between two adjacent dies 40 on the substrate 30. An arch is typically formed by each grounding wire 64. An encapsulated body 50 is then formed over the IC dies 40, bond wires 44 and grounding wires 64, as illustrated in FIG. 6.

The encapsulated IC dies 40, bond wires 44 and grounding wires 64 are divided between adjacent IC dies, as illustrated in FIGS. 7a-7c. A saw, for example, may be used to perform the dividing. When the saw cuts each grounding wire 64 and the encapsulated body 50 in an area between adjacent IC dies 40, the distal end 68 of the grounding wire that is exposed on the outer surface 51 of the encapsulated body 50 is formed.

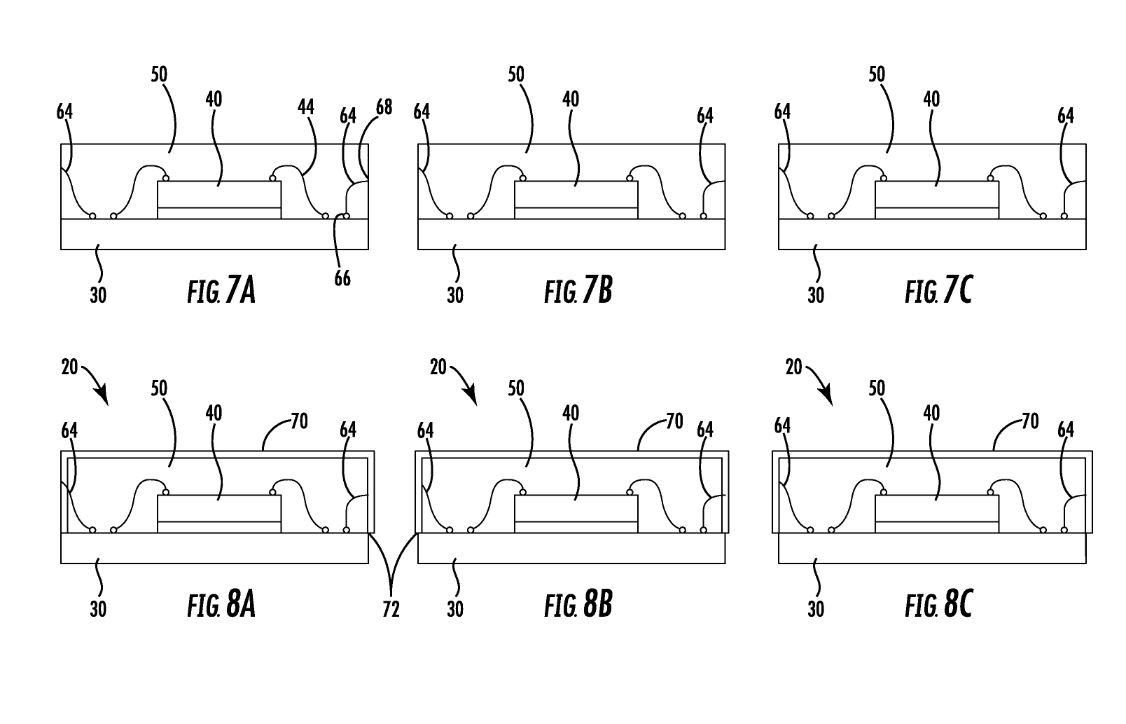

A respective electrically conductive shield layer 70 is formed over each divided encapsulated IC die 40 and the exposed distal ends 68 of the grounding wires 64, as illustrated in illustrated in FIGS. 8a-8c. The conducting material forming the electrically conducted shield layer 70 may be sprayed on like paint. A spray of conductive material is applied to the encapsulated body 50. The electrically conducted shield layer 70 is advantageously grounded via the distal end 68 of each grounding wire 64. This helps to simplify the manufacturing process of the IC packages 20. A physical vapor deposition (PVD) process may be used to form the electrically conductive shield layers 70. Since the encapsulated IC dies 40 have been divided, this allows the bottom edge 72 of the electrically conductive shield layer 70 to be in contact with the substrate 30.

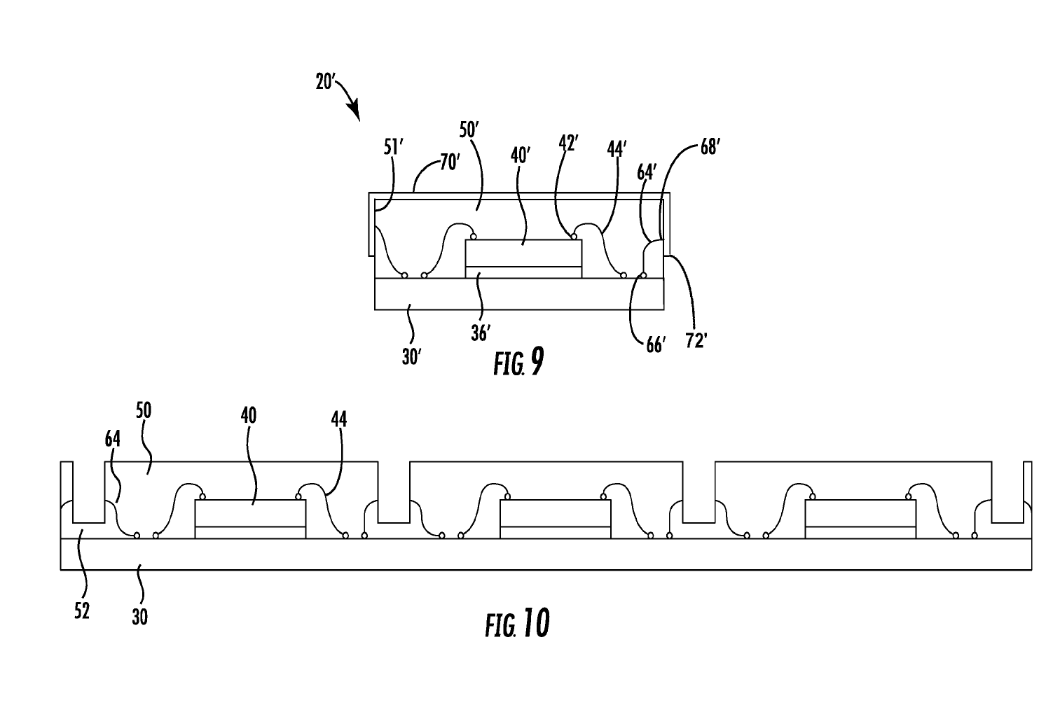

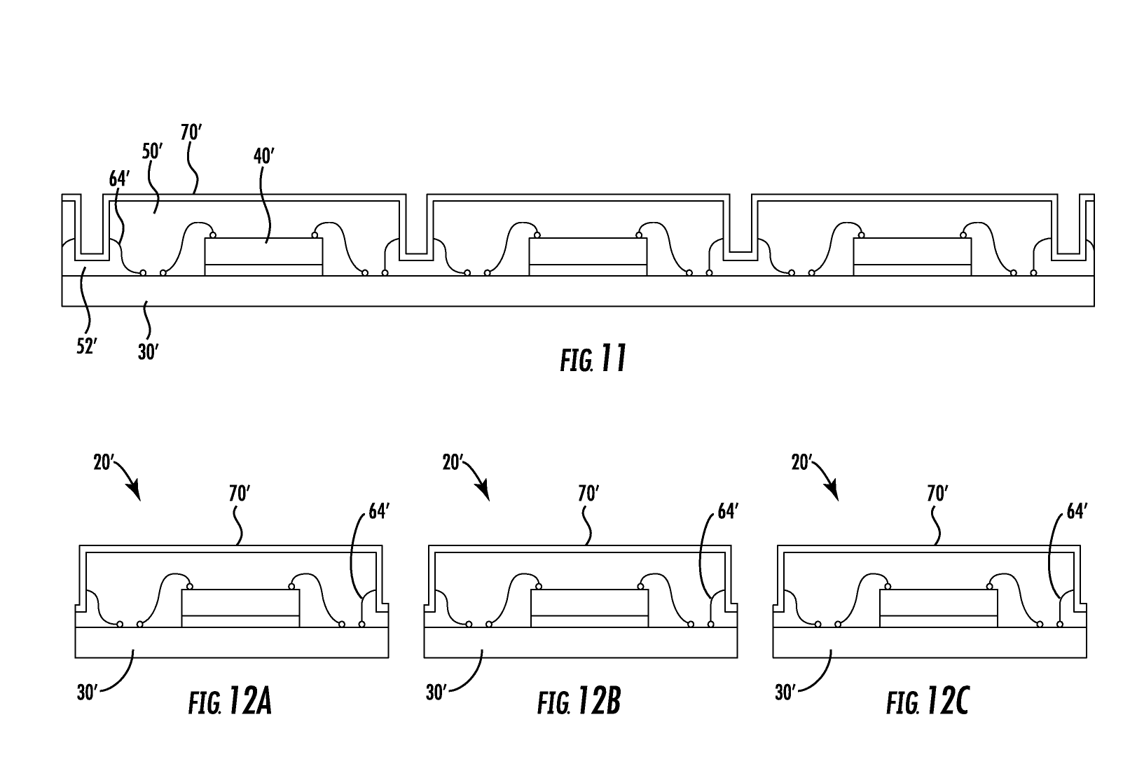

Referring now to FIG. 9, another embodiment of the IC package 20′ will be discussed. In this embodiment, the bottom edge 72′ of the electrically conductive shield layer 70′ is spaced above the substrate 30′. The is based on removing a portion of the encapsulated body 50′ between adjacent IC dies 40′ to expose the respective grounding wires 64′ on the outer surfaces 51′ thereof before providing the electrically conductive shield layer 70′, as illustrated in FIG. 10.

A saw, for example, partially cuts through the encapsulated body 50′ and stops below the respective grounding wires 64′. A portion 52′ of the encapsulated body thus remains on the substrate 30′ between adjacent IC dies 40′. When the saw cuts each grounding wire 64′ and the encapsulated body 50′ in the area between adjacent IC dies 40′, the distal end 68′ of the grounding wire that is exposed on the outer surface 51′ of the encapsulated body 50′ is formed.

The electrically conductive shield layer 70′ is formed over each partially cut encapsulated IC die 40′ and the exposed distal ends 68′ of the grounding wires 64′, as illustrated in illustrated in FIG. 11. The electrically conductive shield layer 70′ is also formed over each remaining portion 52′ of the encapsulated body 50′ between adjacent IC dies 40′ on the substrate 30′. As noted above, a physical vapor deposition (PVD) process may be used to form the electrically conductive shield layer 70′.

Since the encapsulated IC dies 40′ have only been partially cut, this causes the bottom edge 72′ of the electrically conductive shield layer 70′ to be spaced above the substrate 30′. With the gap between the substrate 30′ and the electrically conductive shield layer 70′, the IC package 20′ may be more susceptible to EMI. As a preventive measure, a plurality of grounding wires 64 are used so as to create a shield across the gap.

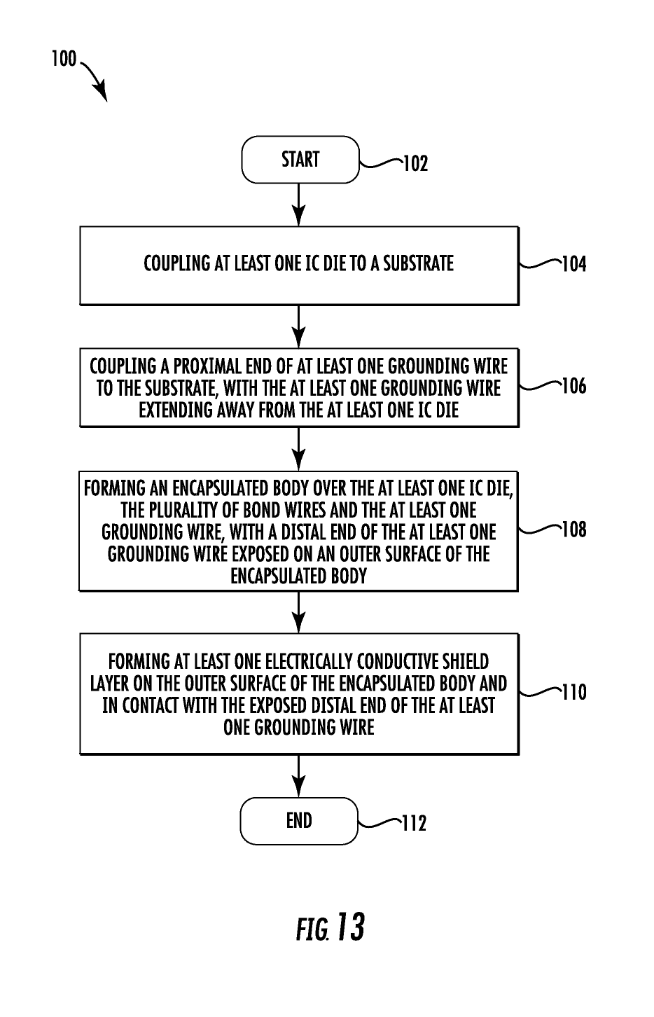

Referring now to FIGS. 12a-12c, the substrate 30′, the remaining portion 52′ of the encapsulated body and the electrically conductive shield layer 70′ between the adjacent IC dies 40′ are divided. This provides the respective IC packages 20′ as illustrated in FIG. 8.

Referring now to FIG. 13, a flowchart 100 for making at least one IC package 20, 120 with a grounded electrically conductive shield layer 70, 170 will be discussed. From the start (Block 102), the method includes coupling at least one IC die 40, 140 to a substrate 30, 130 at Block 104. The IC die 40 may be coupled to the substrate 30 via wire bonds 42 as illustrated in FIG. 1. Alternatively, the IC die 140 may be configured as a flip-chip and is directly bonded to the substrate 130 as illustrated in FIG. 2.

A proximal end 66, 166 of at least one grounding wire 64, 164 is coupled to the substrate 30, 130 at Block 106, with the at least one grounding wire 64, 164 extending away from the at least one IC die 40, 140.

The method further includes forming an encapsulated body 50, 150 over the at least one IC die 40, 140, and the at least one grounding wire 64, 164 at Block 108, with a distal end 68, 168 of the at least one grounding wire being exposed on an outer surface 51, 151 of the encapsulated body 50, 150. For the wire bonded IC die 40, the plurality of bond wires 44 are also in the encapsulated body 50.

At least one electrically conductive shield layer 70, 170 is formed at Block 110 on the outer surface 51, 151 of the encapsulated body 50, 150 and in contact with the exposed distal end 68, 168 of the at least one grounding wire 64, 164.

In view of the IC package 20 illustrated in FIG. 1 where a bottom edge 72 of each electrically conductive shield layer 70 is in contact with the substrate 30, the at least one grounding wire 64 extends between adjacent IC dies 40 and the at least one IC die 40 may comprise a plurality of IC dies, the at least one electrically conductive shield layer 70 may comprise a plurality of electrically conductive shield layers. In this case, the method further includes dividing the substrate 30, the at least one grounding wire 64 and the encapsulated body 50 between adjacent IC dies 40 to expose the respective grounding wires 64 on the outer surfaces 51 of a divided encapsulated body before providing the plurality of electrically conductive shield layers 70. These method steps are also applicable to the IC package 120 illustrated in FIG. 2.

In view of the IC package 20′ illustrated in FIG. 9 where a bottom edge 72′ of each electrically conductive shield layer 70′ is spaced above the substrate 30′, the at least one IC die 40′ may comprise a plurality of IC dies, and the at least one grounding wire 64′ extends between adjacent IC dies. In this case, the method further includes removing a portion of the encapsulated body 50′ and the at least one grounding wire 64′ between adjacent IC dies 40′ to expose the respective grounding wires 64′ on the outer surfaces 51′ of the encapsulated body before providing the at least one electrically conductive shield layer 70′; and dividing the substrate 30′, a remaining portion 52′ of the encapsulated body 50′ and the at least one electrically conductive shield layer 70′ between the adjacent IC dies 40′. These method steps are also applicable to the IC package 120 illustrated in FIG. 2. The method ends at Block 112.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

1. An integrated circuit (IC) package comprising:
a substrate;
an IC die carried by the substrate;
an encapsulated body over the IC die;
at least one grounding wire within the encapsulated body and comprising a proximal end coupled to the substrate, and a distal end exposed on an outer surface of the encapsulated body; and
an electrically conductive shield layer on the outer surface of the encapsulated body and in contact with the distal end of the at least one grounding wire, wherein a bottom edge of the electrically conductive shield layer directly contacts the substrate.

2. (canceled)

3. The IC package according to claim 1 wherein a bottom edge of said electrically conductive shield layer is spaced above said substrate.

4. The IC package according to claim 1, wherein the distal end of the at least one grounding wire is spaced above the substrate.

5. The IC package according to claim 1 wherein said IC die is configured as a flip-chip comprising a plurality of bond pads bonded to said substrate.

6. The IC package according to claim 1, wherein
the IC die comprises a plurality of bond pads,
the IC package further comprises a plurality of bond wires extending from the plurality of bond pads to the substrate, and
the encapsulated body is over the IC die and the plurality of bond wires.

7. The IC package according to claim 6, wherein each of the plurality of bond wires has a cross-sectional size and shape, and wherein the at least one grounding wire has the cross-sectional size and shape.

8. The IC package according to claim 6, wherein
each of the plurality of bond wires extend to a height above the substrate,
the at least one grounding wire extends to the height above the substrate, and
the height is within +/−20% of each bond wire and the at least one grounding wire.

9. The IC package according to claim 6, wherein each of the plurality of bond wires comprises a metal material, and wherein the at least one grounding wire comprises the metal material.

10. The IC package according to claim 1, wherein
the electrically conductive shield layer comprises a side,
the at least one grounding wire comprises a plurality of grounding wires comprising respective distal ends exposed on the outer surface of the encapsulated body, and
the respective distal ends are in direct contact with the side of the electrically conductive shield layer.

11. The IC package according to claim 1, wherein
the electrically conductive shield layer comprises a first side and a second side different from the first side,
the at least one grounding wire comprises a plurality of grounding wires comprising respective distal ends exposed on the outer surface of the encapsulated body,
a first subset of the respective distal ends are in direct contact with the first side, and
a second subset of the respective distal ends are in direct contact with the second side.

12. The IC package according to claim 1, wherein the electrically conductive shield layer comprises a thickness within a range of 1-100 microns.

13. An integrated circuit (IC) package comprising:
a substrate;
an IC die carried by the substrate;
an encapsulated body over the IC die;
at least one grounding wire within the encapsulated body and comprising a proximal end coupled to the substrate, and a distal end exposed on an outer surface of the encapsulated body; and
an electrically conductive shield layer comprising a concave region, wherein
the concave region comprises a horizontal top surface and one or more vertical surfaces, the one or more vertical surfaces making substantially right angles with the horizontal top surface, and
the horizontal top surface and the one or more vertical surfaces directly contact the outer surface of the encapsulated body and the distal end of the at least one grounding wire so that gapless contact is made between the outer surface and each of the horizontal top surface and the one or more vertical surfaces.

14. The IC package according to claim 13, wherein a bottom edge of electrically conductive shield layer directly contacts the substrate.

15. The IC package according to claim 13 wherein a bottom edge of said electrically conductive shield layer is spaced above said substrate.

16. The IC package according to claim 13 wherein the distal end of said at least one grounding wire is spaced above said substrate.

17. The IC package according to claim 13, wherein
the at least one grounding wire comprises a plurality of grounding wires comprising respective distal ends exposed on the outer surface of the encapsulated body, and
each of the respective distal ends are in direct contact with a vertical surface of the one or more vertical surfaces.

18. The IC package according to claim 13, wherein
the one or more vertical surfaces comprises a plurality of vertical surfaces,
the at least one grounding wire comprises a plurality of grounding wires comprising respective distal ends exposed on the outer surface of the encapsulated body,
a first subset of the respective distal ends are in direct contact with a first vertical surface of the plurality of vertical surfaces, and
a second subset of the respective distal ends are in direct contact with a second vertical surface of the plurality of vertical surfaces.

19-28. (canceled)

29. The IC package according to claim 1, wherein an adhesive is not disposed between the electrically conductive shield layer and the encapsulated body.

30. The IC package according to claim 13, wherein an adhesive is not disposed between the electrically conductive shield layer and the encapsulated body.

31. The IC package according to claim 13, wherein
the IC die comprises a plurality of bond pads,
the IC package further comprises a plurality of bond wires extending from the plurality of bond pads to the substrate, and
the encapsulated body is disposed over the plurality of bond wires.

32. The IC package according to claim 31, wherein each of the plurality of bond wires comprise a cross-sectional size and shape, and wherein the at least one grounding wire comprises the cross-sectional size and shape.

33. The IC package according to claim 32, wherein each of the plurality of bond wires comprise a metal material, and wherein the at least one grounding wire comprises the metal material.

34. An integrated circuit (IC) package comprising:
a substrate;
an IC die disposed over the substrate;
an encapsulated body disposed over the substrate and surrounding the IC die;
a grounding wire disposed within the encapsulated body, the grounding wire comprising a proximal end coupled to the substrate, and a distal end exposed on an outer surface of the encapsulated body; and
an electrically conductive shield layer disposed conformally over the encapsulated body, the electrically conductive shield layer physically contacting the outer surface of the encapsulated body and the distal end of the grounding wire, wherein the electrically conductive shield layer overlaps an exposed portion of the substrate.

35. The IC package according to claim 34, wherein the electrically conductive shield layer physically contacts the exposed portion of the substrate.

36. The IC package according to claim 34, wherein the distal end of the at least one grounding wire is spaced above the substrate.

37. The IC package according to claim 34, wherein
the electrically conductive shield layer comprises a first side and a second side different from the first side,
the at least one grounding wire comprises a plurality of grounding wires comprising respective distal ends exposed on the outer surface of the encapsulated body,
a first subset of the respective distal ends are in direct contact with the first side, and
a second subset of the respective distal ends are in direct contact with the second side.

38. An integrated circuit (IC) package comprising:
a substrate;
a semiconductor die disposed over the substrate;
an encapsulated body disposed over the substrate and surrounding the semiconductor die, the encapsulated body comprising an outer surface facing away from the semiconductor die, the outer surface comprising a bottom surface parallel to a major surface of the semiconductor die and sidewalls;
a grounding wire disposed within the encapsulated body, the grounding wire comprising a proximal end coupled to the substrate, and a distal end exposed on one of the sidewalls of the outer surface; and
a metal layer lining the encapsulated body, the metal layer physically contacting the sidewalls, the bottom surface of the outer surface, and the distal end of the grounding wire, wherein the metal layer overlaps an exposed portion of the substrate.

39. The IC package according to claim 38, wherein the metal layer physically contacts the exposed portion of the substrate.

40. The IC package according to claim 38, wherein the distal end of the at least one grounding wire is spaced above the substrate.

41. The IC package according to claim 38, wherein
the metal layer lining comprises a first side and a second side different from the first side,
the at least one grounding wire comprises a plurality of grounding wires comprising respective distal ends exposed on the outer surface of the encapsulated body,
a first subset of the respective distal ends are in direct contact with the first side, and
a second subset of the respective distal ends are in direct contact with the second side.
